(19) United States
(12) Patent Application Publication
(10) Pub. No.: US 2008/0094877 A1
(43) Pub. Date: Apr. 24, 2008

(54) FASTER INITIALIZATION OF DRAM MEMORY

(75) Inventor: Eric R. Schneider, Lexington, MA (US)

Correspondence Address: HONEYWELL INTERNATIONAL INC., 101 COLUMBIA ROAD, P O BOX 2245, MORRISTOWN, NJ, 07962-2245, US

(73) Assignee: Honeywell International Inc., Morristown, NJ (US)

(21) Appl. No.: 11/551,426

(22) Filed: Oct. 20, 2006

(51) Int. Cl. G11C 11/24; G11C 7/00

(52) U.S. Cl. 365/149; 365/218

(57) ABSTRACT

A method of initializing dynamic random access memory (DRAM) comprises allocating one or more rows of a plurality of cells in the DRAM; signaling an initialization request to initialize the allocated one or more rows; and simultaneously initializing all cells in each of the one or more allocated rows upon accessing each of the one or more allocated rows.

### BACKGROUND

Dynamic Random Access Memory (DRAM) is a form of electronic memory which is used for information storage for many electronic devices. DRAM is the primary electronic memory used in personal computers.

DRAM is organized as a matrix of several rows and several columns of memory cells. The memory cells hold a logic 0 or 1 value in a capacitor which is gated by a transistor. When the transistor is gated open the value is measured using a sense amplifier which also writes the value back to the capacitor recharging it.

DRAM chips typically have more columns than data input/output (I/O) pins. DRAM access is therefore broken into a row address phase and a column address phase. During the row address phase the row is gated to the sense amplifier. During the column address phase a slice of columns are gated to the chip's I/O pins.

DRAM is controlled by a 3-bit value encoded on the pins: row address strobe (RAS), column address strobe (CAS), and write enable (WE). One of these 3-bit values is used to load a control register inside the DRAM itself. Bits within the control register are used to configure chip operation.

Software applications often zero out blocks of memory for initialization. Software executables zero un-initialized program variables as part of a program load. Memory using Error Detection and Correction (EDAC) logic is typically initialized to 0. Data buffers are often initialized to 0 to support debugging and reliable operation.

### SUMMARY

The above-mentioned problems and other problems are resolved by the present invention and will be understood by reading and studying the following specification.

In one embodiment, a method of initializing dynamic random access memory (DRAM) is provided. The method comprises allocating one or more rows of a plurality of cells in the DRAM, signaling an initialization request to initialize the allocated one or more rows; and simultaneously initializing all cells in each of the one or more allocated rows upon accessing each of the one or more allocated rows.

### BRIEF DESCRIPTION OF THE DRAWINGS

Features of the present invention will become apparent to those skilled in the art from the following description with reference to the drawings. Understanding that the drawings depict only typical embodiments of the invention and are not therefore to be considered limiting in scope, the invention will be described with additional specificity and detail through the use of the accompanying drawings, in which:

FIG. 1 is a block diagram illustrating how a computer system uses memory.

FIG. 2 is a schematic diagram depicting the internal architecture of a conventional DRAM.

FIG. 3 is a schematic diagram depicting internal architecture of a conventional DRAM core.

FIG. 4 is a schematic diagram depicting a conventional DRAM cell.

FIG. 5 is a schematic diagram depicting a conventional DRAM sense amplifier.

FIG. 6 is a schematic diagram depicting a sense amplifier having initialization logic according to one embodiment of the present invention.

FIG. 7 is a block diagram of a computer system using initialization logic according to one embodiment of the present invention.

FIG. 8 is a flow chart depicting a method of initializing DRAM memory according to one embodiment of the present invention

Like reference numbers and designations in the various drawings indicate like elements.

### DETAILED DESCRIPTION

In the following detailed description, embodiments are described in sufficient detail to enable those skilled in the art to practice the present invention. It is to be understood that other embodiments may be utilized without departing from the scope of the present invention. The following detailed description is, therefore, not to be taken in a limiting sense.

Embodiments of the present invention simultaneously initialize a row of DRAM cells. This initialization is performed by altering the sense amplifier and control logic. This initialization is commanded by augmenting standard DRAM control protocols to include initializing a row. Initializing DRAM rows improves DRAM initialization performance by roughly the ratio of the number of columns to the number of I/O pins.

FIG. 1 is a block diagram illustrating how a computer system 100 uses memory. A central processing unit (CPU) (102) may directly access memory (104) from its own CPU bus (106). Alternatively, a memory controller (108) may act as proxy to bridge access from the CPU bus to memory (104) on a separate memory bus (110). DRAM memory is typically accessed by a memory controller which handles the DRAM memory bus protocol including partitioning CPU bus addresses into DRAM row and column addresses.

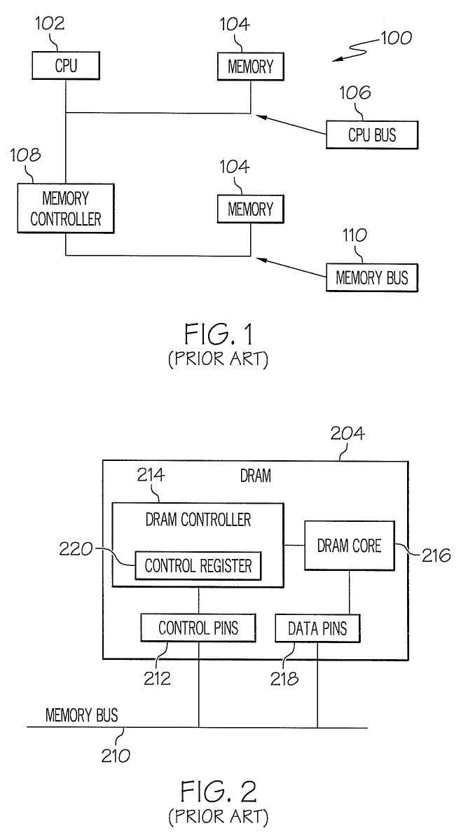

FIG. 2 is a schematic diagram depicting the internal architecture of a conventional DRAM (204). A DRAM memory bus (210) connects DRAM (204) to a memory controller as shown in FIG. 1. Control pins (212) including RAS, CAS, WE and address are processed by a DRAM controller (214). DRAM controller (214) interfaces to a DRAM core (216) to transfer data between core (216) and data pins (218) connected to memory bus (210). One of the 3-bit (RAS, CAS, WE) values is used to load a control register (220) inside DRAM (204) itself with data from data pins (218). Bits within control register (220) are used to configure chip operation. In particular, in embodiments of the present invention, a zero-mode flag can be set in control register (220) to put DRAM (204) in zero mode for initializing cells in DRAM (204) as described below.

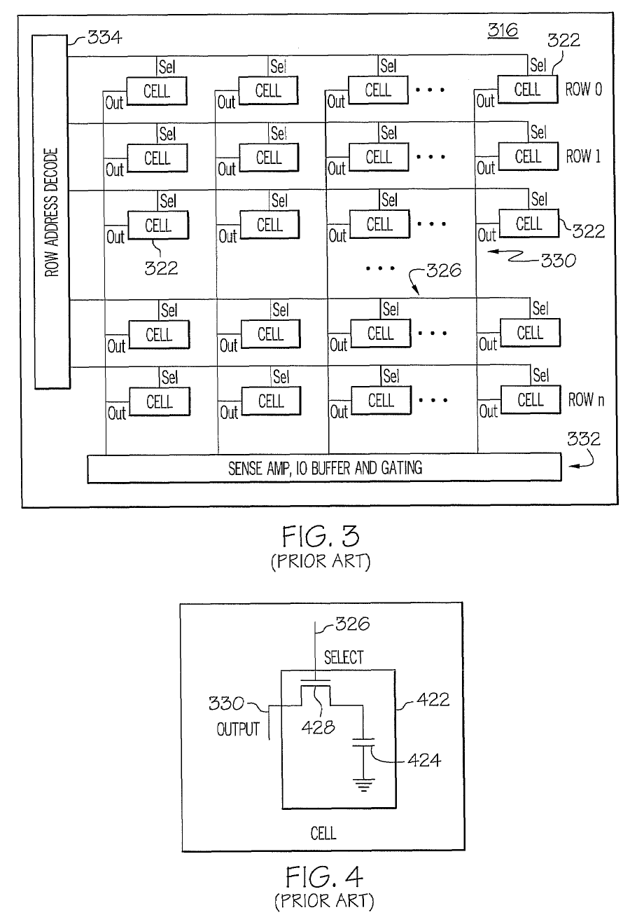

FIG. 3 is a schematic diagram depicting internal architecture of a conventional DRAM core (316). DRAM core (316) is organized as a matrix of several rows and several columns of memory cells (322). An exemplary memory cell (422) is shown in FIG. 4. In FIG. 4, memory cell (422) holds a logic 0 or 1 value in a capacitor (424) which is gated by a select line (326) through a transistor (428) to a digit line (330). When transistor (428) is gated open the value is measured using a sense amplifier (e.g. sense amplifier 332 in FIG. 3.) which also writes the value back to capacitor (424) recharging it.

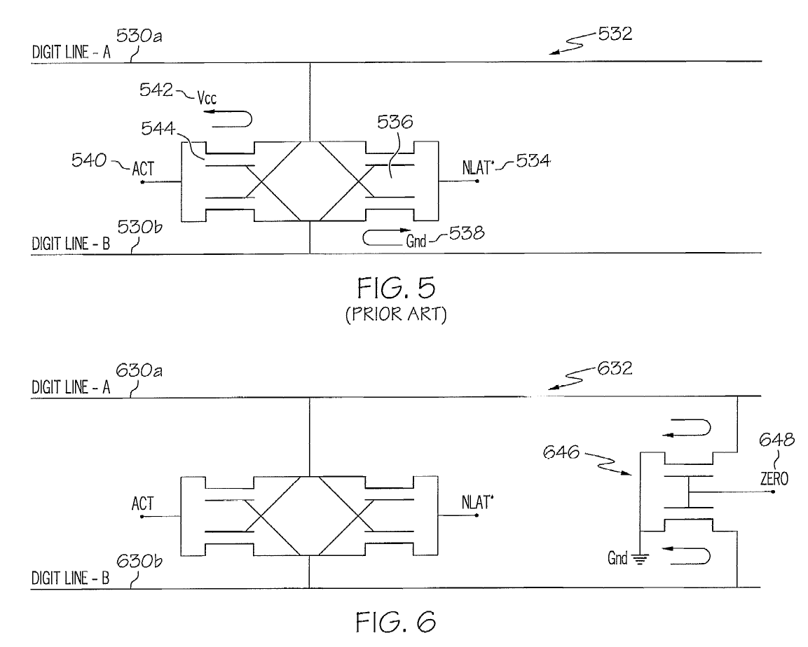

Referring back to FIG. 3, DRAM chips typically have more columns of cells (322) than data input/output (I/O) pins. DRAM access is therefore broken into a row address phase and a column address phase. During the row address phase, the row address is decoded by a row address decoder (334) and the row of cells (322) selected is gated to sense amplifier (332) as described above. During the column address phase a slice of columns are gated to the chip's I/O pins. Sensing cells (322) both reads the contents as well as recharges the cell in typical DRAM chips as explained in FIG. 5.

FIG. 5 is a schematic diagram depicting a conventional DRAM sense amplifier (532). Sensing amplifies the small difference between digit lines (530a and 530b) driving the higher line to voltage Vcc, which represents a logic 1, and the lower line to ground, which represents a logic 0. Digit lines 530 are pre-charged to one half of Vcc. Then a cell (e.g. cell 422) on one of the digit lines 530 is selected connecting its capacitor (e.g. capacitor 424) to the digit line as shown in FIG. 4. The capacitor either slightly raises or lowers the digit line voltage according to its logic value 1 or 0 respectively.

As the signal NLAT (NMOS latch) (534) is brought to ground (538), the gate (536) whose center is connected to the higher voltage (e.g. Line A in this example) conducts the other digit line (e.g. Line B) to ground (538). Shortly after NLAT is driven, the signal ACT (PMOS active pull-up) (540) is brought to voltage level Vcc (542). The gate (544) connected to ground (538) (e.g. Line B) conducts the other digit line (e.g. Line A) to voltage Vcc (542). Hence, the data in a cell coupled to one of digit lines 530 is recharged to its full level (e.g. Vcc or ground). (See Thomas Schwarz, COEN 180, <http://www.cse.scu.edu/˜tschwarz/coen180/LN/DRAM.html>, last accessed Oct. 5, 2006).

FIG. 6 is a schematic diagram of a sense amplifier (632) having initialization logic (646) according to one embodiment of the present invention. Sense amplifier (632) can be used in any appropriate DRAM chip such as in DRAM core (316) in FIG. 3. When a zero-mode flag is set in a DRAM control register (e.g. control register 220 in FIG. 2), initialization logic (646) is coupled to digit lines (630) and a zero signal (648) is used to conduct digit lines (630) to ground, effectively draining the charge from each cell's capacitor (e.g. capacitor 424 in cell 422) connected to one of digit lines (630). Select line (e.g. select line 326 in FIG. 3) is removed, disconnecting the cells from sense amplifier (632) and leaving the capacitor value of each cell coupled to digit lines (630) at logic 0. Zero signal (648) is removed, decoupling initialization logic (646) from digit lines (630).

The zero signal is removed automatically in this embodiment. For example, the zero-mode flag is set only for a determined amount of time or zeroing operations. At the end of that time or number of operations, the zero-mode flag is automatically released. Once the zero-mode flag is released, the DRAM chips stop operating in zero mode (i.e. using initialization logic 646). Alternatively, the zero-mode flag is removed with an active command. Until the command is received in the control register, the zero-mode flag remains set and the DRAM chip continues to operate in zero mode.

Initialization logic (646) is added to all sense amplifiers so that all digit lines can be initialized simultaneously. Hence, embodiments of the present invention enable the initialization of an entire row of cells, whereas conventional DRAM chips initialize cells one location at a time. In addition, by using a persistent zero-mode flag, embodiments of the present invention are able to initialize a row of cells with each row access. Zeroing of the digit line is not restricted to the manner illustrated in FIG. 6. Zeroing may be achieved using modifications to include initialization logic (646) in any component attached to digit lines (630).

In addition, in some embodiments, initialization logic (646) can be switched between connections to ground (638) and connections to buffered data pins to allow initializing DRAM cells to an arbitrary value that is placed on the buffered data-pins. For example, if there are buffered 4 data-pins on the DRAM chip which are holding a value of 5, a DRAM row of cells is initialized to the repeating pattern 5555 . . . by connecting initialization logic (646) to the buffered data-pins.

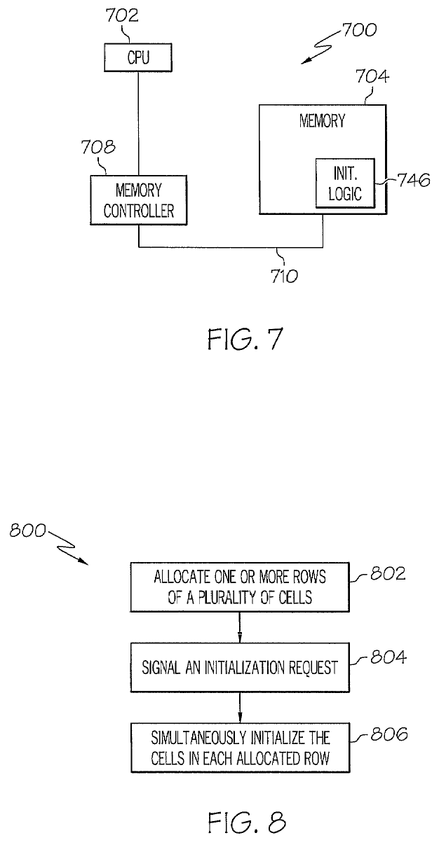

FIG. 7 is a block diagram of a computer system 700 using initialization logic 746 according to one embodiment of the present invention. System 700, in this embodiment, includes a CPU 702, memory controller 708, memory bus 710, and DRAM memory 704. DRAM memory 704 includes initialization logic 746. Initialization logic 746, in this example, is included in each sense amplifier (e.g. sense amplifier 632) in DRAM memory 704. However, it is to be understood that, in other embodiments, initialization logic 746 can be added to any component connected to digit lines (e.g. digit lines 530) in DRAM memory 704.

In operation, computer instructions, such as application, operating system, or device driver software signal an initialization request to initialize cells (e.g. cells 322) in DRAM memory 704. Memory controller 708 can be implemented as an application specific integrated circuit (ASIC), field programmable gate array (FPGA), or other similar device. The function of memory controller 708 in providing an interface between DRAM 704 and CPU 702 can be implemented in instructions written in a hardware description language such as Verilog or Very-High-Speed Integrated Circuit (VHSIC) Hardware Description Language (VHDL). In addition, memory controller 708 is configured, in some embodiments, to determine when to operate in zero-mode operation and sets a zero-mode flag to indicate zero-mode operation. Notably, it is to be understood that, although memory controller 708 is coupled to DRAM memory 704 in this embodiment, embodiments of the present invention are not to be so limited. In particular, CPU 702 can be directly coupled to DRAM memory 704 in other embodiments.

The computer instructions can be implemented in software, firmware, or other computer readable instructions. These instructions are typically stored on any appropriate computer readable medium used for storage of computer readable instructions or data structures. Such computer readable media can be any available media that can be accessed by a general purpose or special purpose computer or processor, or any programmable logic device. Suitable computer readable media may comprise, for example, non-volatile memory devices including semiconductor memory devices such as EPROM, EEPROM, or flash memory devices and other like media.

The computer instructions are also adapted to call various routines to allocate and zero cells. In particular, the instructions are adapted, in some embodiments, to determine the appropriate size of an allocation based on a comparison of the allocation size in the request with a threshold. In particular, the instructions increase the allocation size of a request to equal a row size if the allocation size requested is less than a total row size and greater than the threshold. Subsequent initialization requests are then both possible and performed upon the entire row. In addition, in some embodiments, the instructions are adapted to determine if DRAM memory 704 is adapted to operate in zero-mode operation (e.g. initialize one or more rows simultaneously). Criteria for determining if DRAM memory 704 is to operate in zero-mode operation vary with the system and include, but are not limited to, the amount of memory requested, the DRAM row size, the application, or the operating system. The determination of whether the DRAM chip is to be in row zeroing mode can be handled in CPU 702 software, memory controller 708, DRAM memory 704 itself or any combination of the three. In some embodiments, if it is determined to operate in zero-mode operation, a zero-mode flag is set in a DRAM mode register (e.g. control register 220).

An initialization request to initialize one or more rows is performed, in some embodiments, by setting a zero-mode flag in DRAM control register 220 then accessing the row address of the row to be initialized in DRAM 704. However, it is to be understood that in other embodiments of the present invention, an initialization request to initialize one or more rows can also be performed by any other means which the controller in DRAM 704 can correlate to the zeroing of a row of DRAM memory 704.

In some embodiments, the DRAM controller accesses several DRAM rows while the zero-mode flag is set so as to zero several rows before clearing the bit. The DRAM zero-mode flag, in some embodiments, automatically clears when the row is accessed and zeroed, thus automatically restoring DRAM memory 704 to normal mode. Alternatively, two different zero-mode flags are used, one self-clearing and the other explicitly cleared via an additional command as described above. Finally, in some alternative embodiments, an initialization value is placed on buffered data pins in DRAM memory 704 and coupled to initialization logic 746 to initialize DRAM 704 to a value other than zero as described above.

If the initialization request is not a row zero request, the zero-mode flag is not set and DRAM memory 704 is initialized one location at a time as in a conventional DRAM chip. Hence, while conventional software allocates and initializes DRAM cells one location at a time, embodiments of the present invention, also enable simultaneous initialization of one or more rows of DRAM cells and the corresponding row aligned and sized allocation to allow row initialization. Consequently, DRAM memory 704 is able to be zeroed or initialized at a quicker rate than convention DRAM chips.

FIG. 8 is a flow chart depicting a method 800 of initializing DRAM memory according to one embodiment of the present invention. At 802, one or more rows of a plurality of cells (e.g. cells 322) are allocated. In some embodiments, allocating the one or more rows includes determining if the DRAM is to operate in zero-mode operation. Factors which influence this determination include, but are not limited to, the amount of memory requested, type of DRAM, row size, the application requesting memory, and the operating system being used.

When it is determined to operate in zero-mode operation, a zero-mode flag can be set to indicate such operation to the DRAM memory. The DRAM memory operates in zero-mode operation as long as the flag is set. The zero-mode flag can be released automatically after a set time period or a set number of initialization requests, thereby ceasing zero-mode operation. Alternatively, a persistent zero-mode flag can be used. In such embodiments, the zero-mode flag is released by signaling a command to release the zero-mode flag. If it is determined that the DRAM is not to operate in zero-mode operation, the zero-mode flag is not set. When the zero-mode flag is not set, cells in the DRAM are initialized one location at a time as in conventional DRAM chips.

Allocating the one or more rows, in some embodiments, also includes upsizing the allocation size to units of row size. For example, if an allocation size of a request is smaller than a row size but larger than a threshold value, the allocation size is increased to row boundaries so that the allocation size is in units of row size. Allocating memory in units of row size is advantageous when operating in zero-mode operation since entire rows are initialized when accessed.

At 804, an initialization request is signaled to initialize the allocated rows. For example, a CPU (e.g. CPU 702) can send a request to a control register (e.g. control register 220) to initialize a block of the DRAM memory. At 806, the cells in each of the one or more allocated rows are initialized simultaneously upon being accessed as described above. In particular, in some embodiments, initializing the one or more allocated rows includes coupling a plurality of digit lines to initialization logic (e.g. initialization logic 646) to place an initialization value on the plurality of digit lines. The initialization value can be a zero or non-zero initialization value. For example, the initialization logic can be coupled to ground to place a zero initialization value on the digit lines. Alternatively, the initialization logic can be coupled to at least one buffered data pin to place a non-zero value on the digit lines. The allocated rows of cells are coupled to the digit lines (i.e. accessed) one row at a time. When each row is coupled to the digit lines, each of the cells in the row coupled to the digit lines is simultaneously set to the initialization value. Once the row is initialized, it is decoupled from the digit lines. Similarly, once the DRAM has finished initializing memory, the initialization logic is decoupled from the digit lines.

The present invention may be embodied in other specific forms without departing from its essential characteristics. The described embodiments are to be considered in all respects only as illustrative and not restrictive. The scope of the invention is therefore indicated by the appended claims rather than by the foregoing description. All changes that come within the meaning and range of equivalency of the claims are to be embraced within their scope.

What is claimed is:

1. A method of initializing dynamic random access memory (DRAM), the method comprising:
allocating one or more rows of a plurality of cells in the DRAM;
signaling an initialization request to initialize the allocated one or more rows; and
simultaneously initializing all cells in each of the one or more allocated rows upon accessing each of the one or more allocated rows.

2. The method of claim 1, wherein initializing all cells in each of the one or more allocated rows comprises:
coupling a plurality of digit lines to initialization logic to place an initialization value on the plurality of digit lines; and
simultaneously setting all cells in each of the one or more allocated rows to the initialization value by coupling each of the one or more allocated rows to the plurality of digit lines one row at a time.

3. The method of claim 1, wherein initializing the cells in each of the one or more allocated rows comprises initializing the cells in each of the one or more allocated rows to one of a zero initialization value and a non-zero initialization value.

4. The method of claim 1, wherein allocating one or more rows comprises upsizing a memory allocation size to units of row size.

5. The method of claim 1, wherein allocating one or more rows includes:
determining when to operate in zero-mode operation; and
setting a zero-mode flag if it is determined to operate in zero-mode operation.

6. The method of claim 5, further comprising one of:
releasing the zero-mode flag automatically after one of a set time period and a set number of initialization requests; and
releasing the zero-mode flag after receiving a command to release the zero-mode flag.

7. The method of claim 5, further comprising:
initializing the cells in each of the one or more rows one location at a time if the zero-mode flag is not set.

8. The method of claim 5, wherein determining when to operate in zero-mode operation comprises determining when to operate in zero-mode operation based on one or more of amount of memory requested, type of DRAM, row size, an application requesting memory, and an operating system being used.

9. A dynamic random access memory (DRAM) chip, comprising:
a control register configured to set DRAM chip mode operation;
a plurality of cells, each cell configured to hold a value representing a logic 1 or a logic 0;
a plurality of select lines;
a plurality of digit lines;
a row address decoder configured to decode a row address and select one or more rows of cells via one or more select lines, wherein selecting one or more rows of cells couples each of the plurality of cells to one of the plurality of digit lines; and
initialization logic selectively coupled to the plurality of digit lines when the control register sets the DRAM chip for zero-mode operation, wherein the initialization logic places an initialization value on the plurality of digit lines such that each row of cells selected by the row address decoder is charged simultaneously to the initialization value.

10. The DRAM chip of claim 9, wherein further comprising:
a sense amplifier, the initialization logic being located in the sense amplifier.

11. The DRAM chip of claim 9, wherein the initialization logic is coupled to one of ground and at least one buffered data pin, the initialization value being a non-zero value if the initialization logic is coupled to the at least one buffered data pin.

12. The DRAM chip of claim 9, wherein the control register is configured to set the DRAM chip for zero-mode operation by setting a zero-mode flag.

13. The DRAM chip of claim 12, wherein the control register is configured to release the zero-mode flag automatically after one of a set time period and a set number of zero operations.

14. The DRAM chip of claim 12, wherein the control register is configured to release the zero-mode flag upon receiving a command to cease zero-mode operation.

15. A computer system comprising:
a central processing unit (CPU) configured to signal row initialization requests; and
one or more dynamic random access memory (DRAM) chips, each DRAM chip comprising:
a control register configured to set DRAM chip operation for zero-mode operation based on row initialization requests from the CPU;
a plurality of cells, each cell configured to hold a value representing a logic 1 or a logic 0;
a plurality of select lines;
a plurality of digit lines;
a row address decoder configured to decode a row address and select one or more rows of cells via one or more select lines, wherein selecting one or more rows of cells couples each of the plurality of cells to one of the plurality of digit lines; and
initialization logic selectively coupled to the plurality of digit lines when the control register sets the DRAM chip for zero-mode operation, wherein the initialization logic places an initialization value on the plurality of digit lines such that each row of cells selected by the row address decoder is charged simultaneously to the initialization value.

16. The computer system of claim 15, wherein each of the one or more DRAM chips further comprises a sense amplifier, the initialization logic being located in the sense amplifier.

17. The computer system of claim 15, wherein the initialization logic is coupled to one of ground and at least one buffered data pin, the initialization value being a non-zero value if the initialization logic is coupled to the at least one buffered data pin.

18. The computer system of claim 15, wherein the control register is configured to set the DRAM chip for zero-mode operation by setting a zero-mode flag.

19. The computer system of claim 18, wherein the control register is configured to release the zero-mode flag automatically after one of a set time period and a set number of zero operations.

20. The computer system of claim 18, wherein the control register is configured to release the zero-mode flag upon receiving a command from the CPU to cease zero-mode operation.
